(19) United States
(12) Patent Application Publication
(10) Pub. No.: US 2006/0002075 A1
(43) Pub. Date: Jan. 5, 2006

(54) Integrated removable rack compartment for electrical apparatus

(76) Inventors: Chen Wei-Chieh, Taipei (TW); Yu Wen-Lung, Taipei (TW)

Correspondence Address: Yi-Wen Tseng, 4331 Stevens Battle Lane, Fairfax, VA, 22033, US

(21) Appl. No.: 10/879,105

(22) Filed: Jun. 30, 2004

(51) Int. Cl. H05K 5/00

(52) U.S. Cl. 361/685; 361/683

(57) ABSTRACT

An integrated removable rack compartment is capable of incorporating two or more electrical devices and can be easily and quickly install into or detach from a desktop computer or an electrical instrument. A first storage space and a second storage apace of the integrated removable rack compartment are formed, via bending a metal plate several times, in order to receive various electrical devices with different functions, specifications, and dimensions. Various connecting portions and mount components are utilized in the present invention to secure the electrical devices into the integrated removable rack compartment, and to secure the integrated removable rack compartment into the chassis of a computer or a electrical instrument.

### BACKGROUND OF THE INVENTION

The present invention relates in general to a compartment structure, and more particularly, to an integrated removable rack compartment, which is capable of incorporating two or more electrical devices and can be easily and quickly install into or detach from a desktop computer or an electrical instrument.

Conventional desktop computers, industrial servers, and electrical instruments have a chassis. Various compartments with different shapes can be assembled into the chassis in order to install different electrical devices inside the desktop computer. The chassis not only accommodates the electrical devices but also provides the electrical devices a means of protection during transportation. However, the installation of the electrical devices is difficult for this conventional art. Installation is difficult, because the various compartments are fixed within the chassis and the interior of the chassis is small; the angles and directions a consumer can utilize to screw the electrical devices into the compartments are limited. The consumer has to constantly re-orient the chassis in order to find a better angle or direction for using a screwdriver to secure the electrical devices into their compartments. Similarly, because the removal procedure of the electrical devices is the reverse of the installment procedure, the removal of the electrical devices is difficult as well.

### BRIEF SUMMARY OF THE INVENTION

The present invention is to remedy the aforementioned drawbacks. The present invention refines the compartments to allow a consumer to install the electrical devices into the compartments before they are installed into the chassis. Additionally, the present invention doesn't require any screw in the installation of the electrical devices. A consumer or repairer can quickly and easily install or remove the electrical devices into or from the chassis

The integrated removable rack compartment provided by the present invention is formed via bending a metal plate several times. A first support portion is formed in the middle of the integrated removable rack compartment. First side plates extend vertically from the first support portion. The space between the first side plates is defined as the first storage space, which is utilized to store electrical devices. Second support portions extend horizontally from the first side plates. Second side plates extend vertically from the second support portions. The space between the second side plates is defined as the second storage space, which can be utilized to store electrical devices. Additionally, there are mount portions, which extend horizontally from the second side plates, formed on the integrated removable rack compartment in order to secure the integrated removable rack compartment onto the chassis of a computer or an electrical instrument. Further, different connecting portions are provided on the first and the second side plate in order to secure various electrical devices which may have different functions, specifications, and dimensions.

These and other objectives of the present invention will become obvious to those of ordinary skill in the art after reading the following detailed description of preferred embodiments.

It is to be understood that both the foregoing general description and the following detailed description are exemplary, and are intended to provide further explanation of the invention as claimed.

### BRIEF DESCRIPTION OF THE DRAWINGS

These as well as other features of the present invention will become more apparent upon reference to the drawings therein:

FIG. 1 is a perspective view of an integrated removable rack compartment in accordance with the present invention.

FIG. 2 is a perspective view of a conventional 3.5 inches floppy disk drive and an integrated removable rack compartment in accordance with the present invention, illustrating one usage of the integrated removable rack compartment.

FIG. 3 is a perspective view of a conventional 3.5 inches hard disk drive and an integrated removable rack compartment in accordance with the present invention, illustrating one usage of the integrated removable rack compartment.

FIG. 4 is a perspective view of a conventional CD drive and an integrated removable rack compartment with a 3.5 inches floppy disk drive installed, illustrating one usage of the integrated removable rack compartment.

FIG. 5 is a perspective view of memory card readers and an integrated removable rack compartment with a floppy disk drive and a CD drive installed, illustrating one usage of the integrated removable rack compartment.

FIG. 6 is a perspective view of an integrated removable rack compartment fully utilized by different electrical devices.

FIG. 7 is a perspective view of an integrated removable rack compartment fully utilized by different electrical devices, before being installed into a computer chassis.

FIG. 8 is a perspective view of a computer chassis into which the integrated removable rack compartment fully utilized by different electrical devices is installed.

### DETAILED DESCRIPTION OF THE INVENTION

Reference will now be made in detail to the preferred embodiments of the present invention, examples of which are illustrated in the accompanying drawings. Wherever possible, the same reference numbers are used in the drawings and the description to refer to the same or like parts.

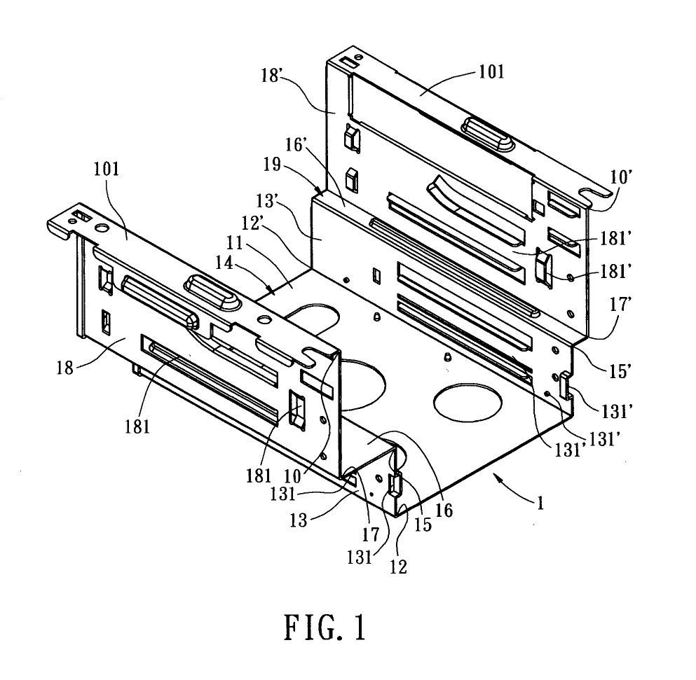

Referring to FIG. 1, a perspective view of one embodiment of an integrated removable rack compartment 1 in accordance with the present invention is shown. The integrated removable rack compartment 1 is provided to incorporate two or more different electrical devices which could have different dimensions, specifications, and functions. The integrated removable rack compartment 1 can be removed entirely away from the chassis. The electrical devices can be installed into the integrated removable rack compartment 1 before the integrated removable rack compartment 1 is mounted into the chassis. The present invention provides consumers a quick and easy installment of the electrical devices. The present invention is also convenient for a consumer to remove the electrical devices in order to replace or upgrade the electrical devices.

The configuration of the integrated removable rack compartment 1 is formed by bending a metal plate several times. A first support portion 11 is formed in the middle of the integrated removable rack compartment 1. First bend portions 12, 12′ are formed at both free ends of the support portion 11. First side plates 13, 13′ extends vertically from the first bend portions 12, 12′. The space between the first side plates 13, 13′ is defined as the first storage space 14, which is utilized to store electrical devices.

Second bend portion 15, 15′ are formed at the free ends of the first side plates 13, 13′. Second support portions 16, 16′ extend horizontally from the second bend portions 15, 15′. Third bend portions 17, 17′ are formed at the free ends of the second support portions 16, 16′. Second side plates 18, 18′ extend vertically from the third bend portions 17, 17′. The space between the second side plates 18, 18′ is defined as the second storage space 19. The second storage space 19 is also utilized to store electrical devices.

Fourth bend portions 10,10′ are formed at the free ends of the second side plates 18, 18′. Mount portions 101, 101′ extend horizontally from the fourth bend portions 10, 10′, which are utilized to secure the integrated removable rack compartment 1 onto the chassis. Additionally, there are connecting portions 131, 131′ formed on the first side plates, and connecting portions 181, 181′ formed on the second side plates. The connect portions 131, 131′, 181, 181′ are utilized to secure different electrical devices inside the integrated removable rack compartment 1.

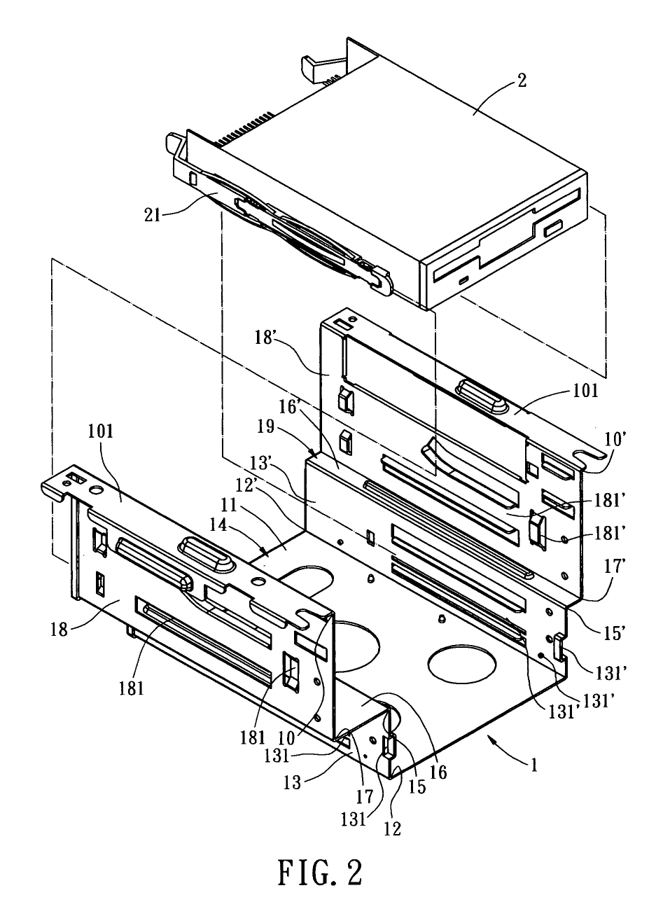

Referring to FIG. 2, one usage of the integrated removable rack compartment 1 is illustrated by a perspective view of a conventional 3.5 inches floppy disk drive and an integrated removable rack compartment. The first storage space 14 formed between the first side plates 13, 13′ can be utilized to receive a first electrical device 2, which can be, but is not limited to, a 3.5 inches floppy disk. The first electrical device 2 has mount components 21, which are conventional art not further described here, on its both sides. When the first electrical device 2 is assembled into the integrated removable rack compartment 1, the mount components 21 are oriented by and secured to connecting portions 131, 131′ of the first side plates 13, 13′. Thereby, the first electrical device 2 is secured firmly inside the first storage space 14.

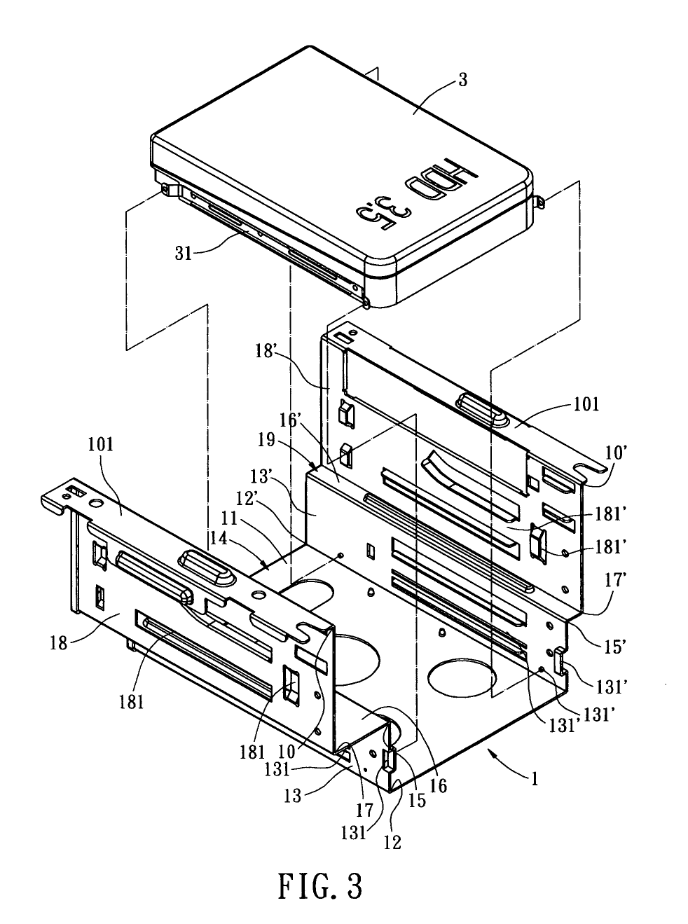

Referring to FIG. 3, another usage of the integrated removable rack compartment 1 is illustrated by a perspective view of a conventional 3.5 inches hard disk and an integrated removable rack compartment. The first storage space 14 formed between the first side plates 13, 13′ can be utilized to receive a second electrical device 3, which can be, but is not limited to, a 3.5 inches hard disk drive. The second electrical device 3 has mount components 31, which are conventional art not further described here, on its both sides. When the second electrical device 3 is assembled into the integrated removable rack compartment 1, the mount components 31 are oriented by and secured to connecting portions 131, 131′ of the first side plates 13, 13′. Thereby, the second electrical device 3 is secured firmly inside the first storage space 14.

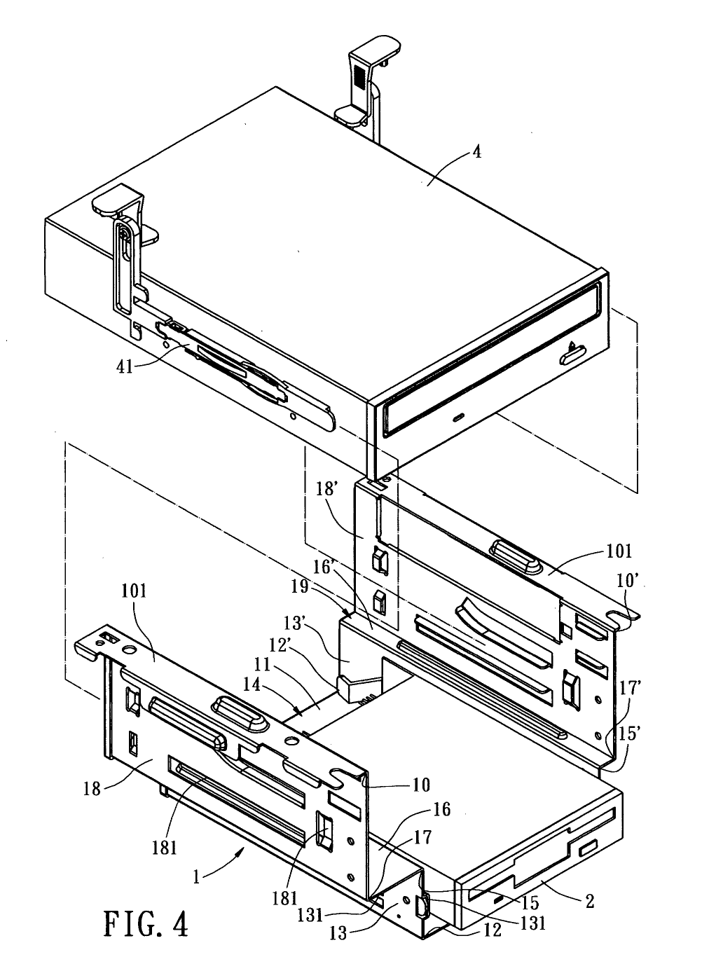

Referring to FIG. 4, a further usage of the integrated removable rack compartment 1 is illustrated by a perspective view of a conventional CD drive 4 and an integrated removable rack compartment 1 with a 3.5 inches floppy disk drive 2 installed. After either the first electrical device 2 or the second electrical device 3 has been installed into the integrated removable rack compartment 1, a third electrical device 4 can be installed into the second storage space 19 formed between the second side plates 18, 18′. The third electrical device 4 can be, but is not limited to, a CD drive 4. The third electrical device 4 also has mount components 41 installed on its both sides. When the third electrical device 4 is assembled into the second storage space 19, the mount components 41 are oriented by and secured to connecting portions 181, 181′ of the second side plates 18, 18′. Thereby, the third electrical device 4 is secured firmly inside the second storage space 19.

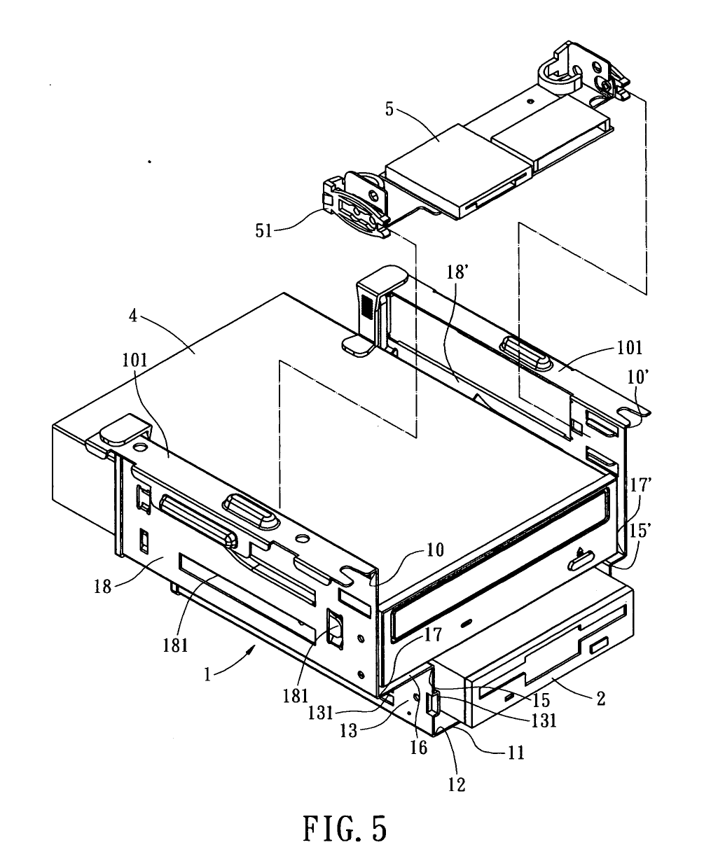

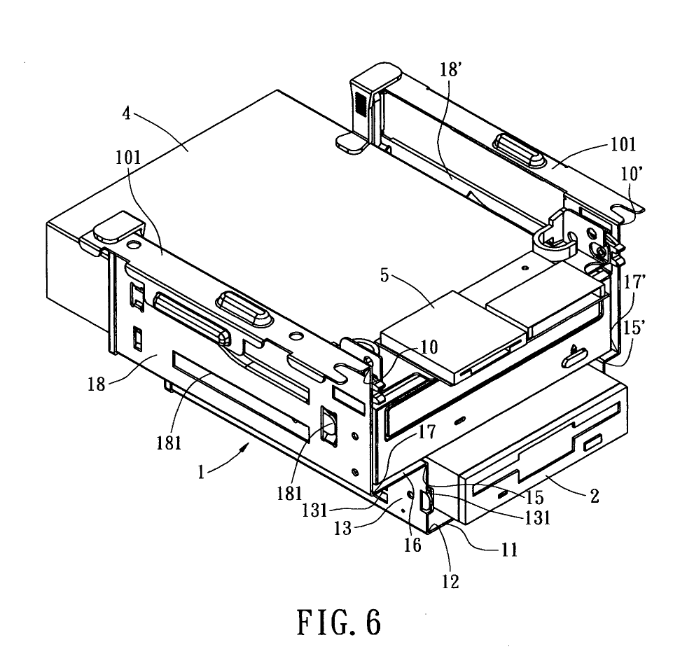

Referring to FIG. 5 and FIG. 6, still another usage of the integrated removable rack compartment 1 is illustrated by two perspective views. After either the first electrical device 2 or the second electrical device 3 and the third electrical device 4 have been installed into the integrated removable rack compartment 1, there is still a narrow space left in the integrated removable rack compartment 1. The narrow space is above the third electrical device 4, and is between the second side plates 18, 18′. This narrow space can be utilized to install the fourth electrical device 5, which can be, but not limited to, a memory card reader. The fourth electrical device 5 also has mount components 51 installed on its both sides. When the fourth electrical device 5 is assembled into the second storage space 19, the mount components 51 are oriented by and secured to connecting portions 181, 181′ of the second side plates 18, 18′. Thereby, the fourth electrical device 5 is secured firmly inside the second storage space 19.

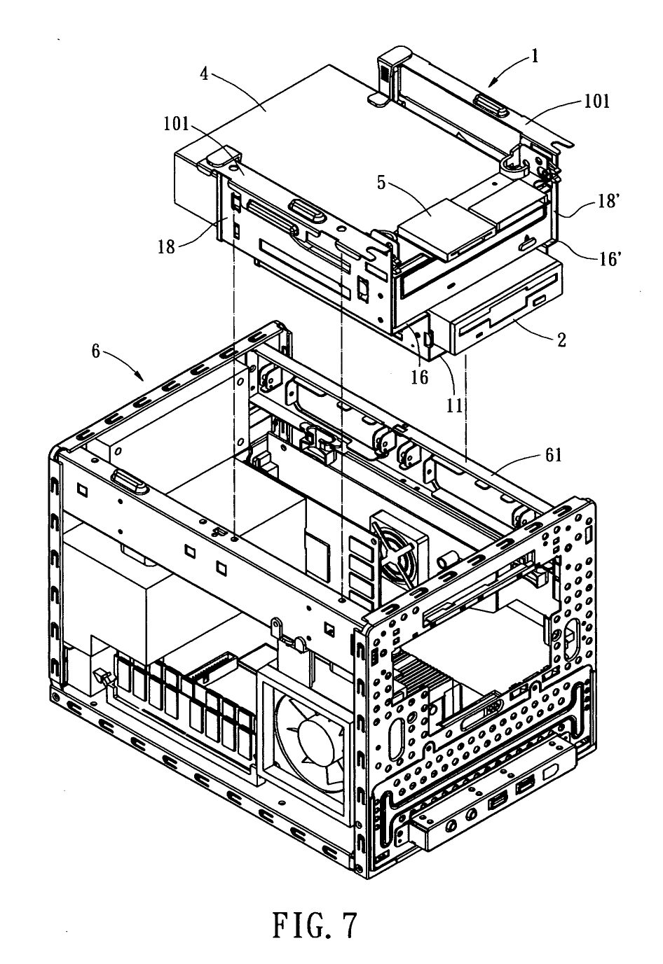

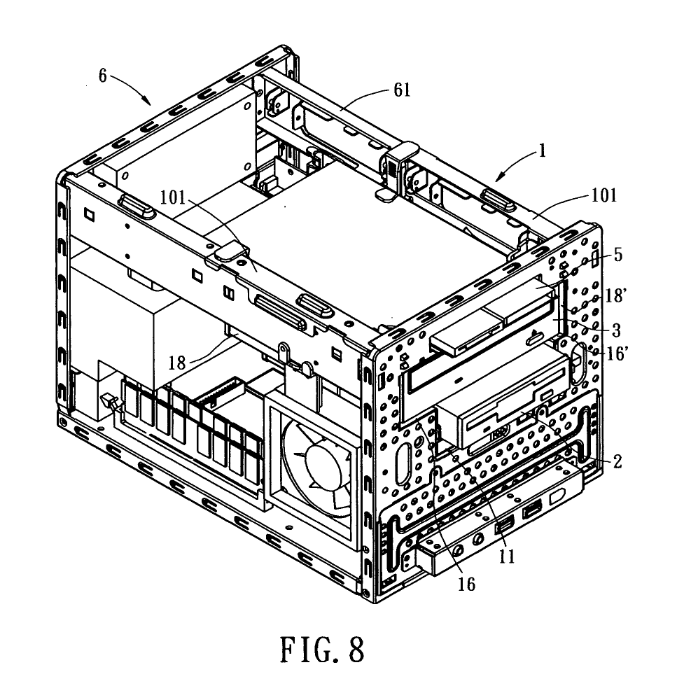

Referring to FIG. 7 and FIG. 8, perspective views of an integrated removable rack compartment 1 fully utilized by different electrical devices before and after installed into the computer chassis are shown respectively. After the various electrical devices 2, 3, 4, 5 have been assembled into the integrated removable rack compartment 1, this assembly can be mounted into the main frame 61 of the computer chassis 6 without using any screw components. A consumer or repairer can quickly and easily install or remove the electrical devices into or from the computer chassis 6.

While an illustrative and presently preferred embodiment of the invention has been described in detail herein, it is to be understood that the inventive concepts may be otherwise variously embodied and employed and that the appended claims are intended to be construed to include such variations except insofar as limited by the prior art.

What is claimed is:

1. An integrated removable rack compartment, which is capable of incorporating two or more electrical devices and can be easily and quickly install into or detach from a desktop computer or an electrical instrument, the rack compartment comprising:
a first support portion having two first side plates extending vertically from two opposite free ends thereof respectively to define a first storage space; and
two second support portions extending horizontally from the free ends of the first side plates respectively, wherein two second side plates extends vertically from the free ends of the second support portions respectively to defined a second storage space,
whereby at least two electrical devices having different functions, specifications, and dimensions can be received in the first and the second storage space, respectively.

2. The integrated removable rack compartment of claim 1, further comprising a mount portion extending horizontally from each second side plate to mount on a chassis of the desk computer or the electrical instrument.

3. The integrated removable rack compartment of claim 1, further comprising a plurality of connecting portions with different shapes formed on the first and the second side plates.

4. The integrated removable rack compartment of claim 1, wherein the electrical device is a floppy disk drive.

5. The integrated removable rack compartment of claim 1, wherein the electrical device is a hard disk drive.

6. The integrated removable rack compartment of claim 1, wherein the electrical device is a compact disk drive.

7. The integrated removable rack compartment of claim 1, wherein the electrical device is a memory card reader.

8. The integrated removable rack compartment of claim 1, wherein the electrical device has a mount component installed on each side thereof.
